(19) United States
(12) Patent Application Publication
(10) Pub. No.: US 2011/0058314 A1
(43) Pub. Date: Mar. 10, 2011

(54) COVER ASSEMBLY FOR PORTABLE ELECTRONIC DEVICE

(75) Inventor: CHAO-YUAN CHENG, Shindian (TW)

(73) Assignee: FIH (HONG KONG) LIMITED, Kowloon (HK)

(21) Appl. No.: 12/640,132

(22) Filed: Dec. 17, 2009

(30) Foreign Application Priority Data
Sep. 4, 2009 (CN) 200920309650.9

(51) Int. Cl. H05K 7/00

(52) U.S. Cl. 361/679.01

(57) ABSTRACT

A portable electronic device is provided. A portable electronic device comprises a cover member, a housing, and a shaft. The cover member comprises a main portion, and the main portion comprises a first masking portion and a second masking portion. The housing comprises a bottom wall and a peripheral wall protruding from the bottom wall. The peripheral wall defines a first port and a second port. The first masking portion is received in the first port. The second masking portion is received in the second port. The shaft protrudes from the main portion and locates between the first masking portion and the second masking portion. The cover member is rotatably mounted to the housing via the shaft.

### BACKGROUND

1. Technical Field

The present disclosure relates to a cover assembly and, particularly, to a cover assembly used in a portable electronic device.

2. Description of Related Art

Portable electronic devices (e.g., mobile phones) usually have a plurality of ports for insertion of components (e.g., earphones and power plugs). Correspondingly, kinds of covers may be used to cover and protect the earphone holes from e.g., water and dust.

A typical protective cover is often made of rubber and is fixedly connected to the mobile phone by a flexible strip adjacent to the port. The covering/exposing of the port is achieved by bending the earphone cover towards/away from the port around the flexible strip.

However, the flexible strip may not endure frequent use and break.

Therefore, there is room for improvement within the art.

### BRIEF DESCRIPTION OF THE DRAWINGS

Many aspects of the cover assembly for portable electronic device can be better understood with reference to the following drawings. These drawings are not necessarily drawn to scale, the emphasis instead being placed upon clearly illustrating the principles of the present cover assembly. Moreover, in the drawings like reference numerals designate corresponding members throughout the several views.

FIG. 1 is an exploded, isometric view of a cover assembly for portable electronic device, in accordance with an exemplary embodiment.

FIG. 2 is similar to FIG. 1, but viewed from another aspect.

FIG. 3 is an enlarged, isometric view of the cover member shown in FIG. 1.

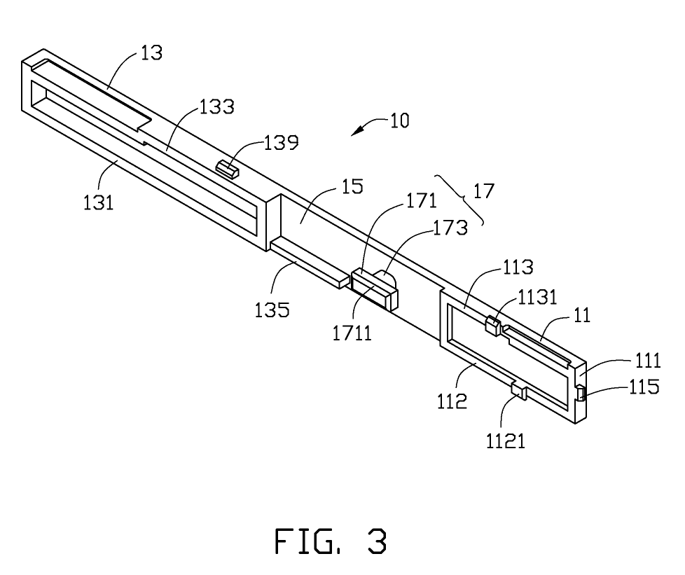

FIG. 4 is an assembly view of the cover assembly shown in FIG. 1.

FIG. 5 is a schematic view showing an opening/closing operation of the cover assembly shown in FIG. 4.

### DETAILED DESCRIPTION

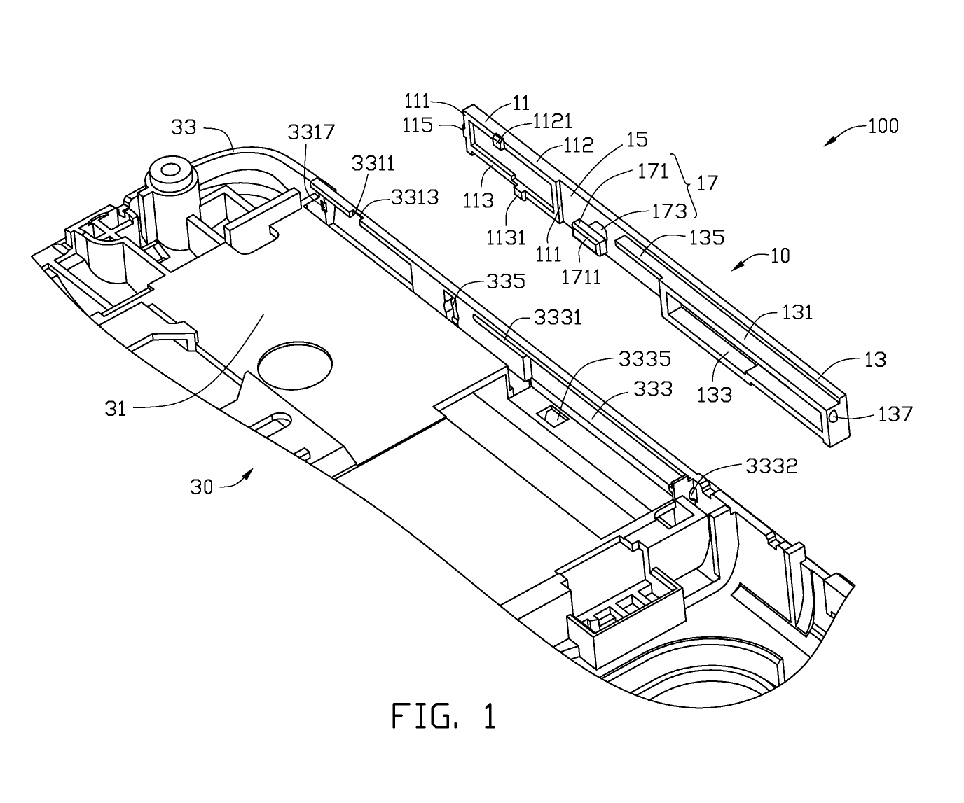

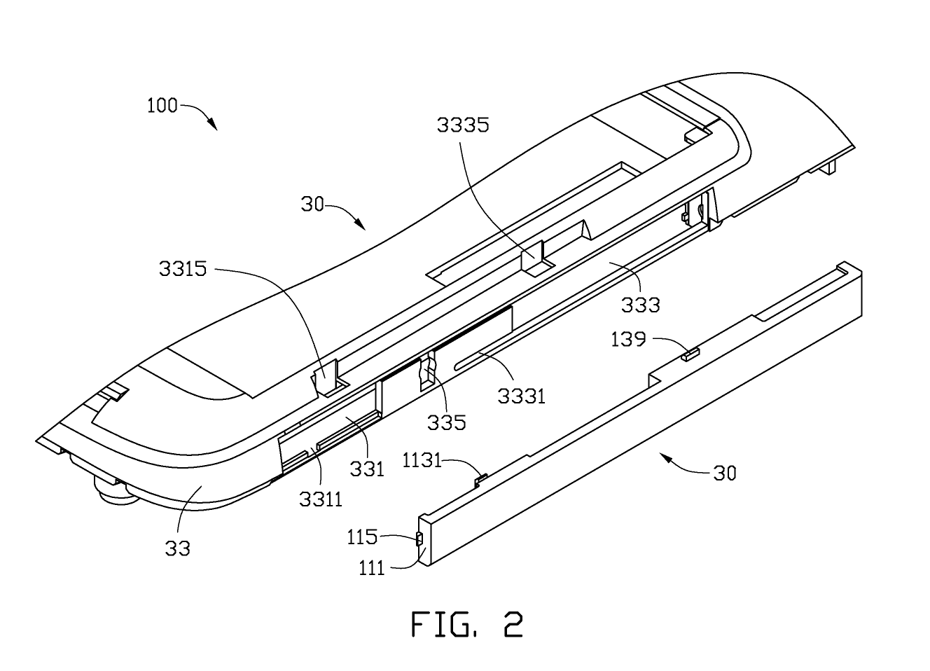

FIGS. 1 and 2 show an exemplary cover assembly 100. The cover assembly 100 includes a cover member 10 and a housing 30. The cover member 10 is rotatably connected to the housing 30.

The cover member 10 includes a main portion 15. The main portion 15 includes a first masking portion 11 and a second masking portion 13. The first masking portion 11 and the second masking portion 13 are formed at two opposite ends of the main portion 15. The first masking portion 11 is enclosed by two short sides 111, a first long side 112, and a second long side 113. The two short sides 111 are opposite to each other. The two long sides 112, 113 are opposite to each other. An embedding block 115 protrudes from the short side 111 away from the second masking portion 13. The embedding block 115 is embedded in the housing 30. A resisting block 1121 protrudes from the first long side 112, used to resist the housing 30. A latch block 1131 protrudes from the second long side 113, used to latch with the housing 30. The second masking portion 13 is surrounded by a first brim 131 and a second brim 133 opposite to the first brim 131. The first brim 131 and the second brim 133 extend along the first long side 112 and the second long side 113. A latch board 135 protrudes from the first brim 131 towards the first masking portion 11. The latch board 135 is for latching with the housing 30. A protrusion 137 protrudes from one end of the first brim 131 away from the first masking portion 11. The protrusion 137 is received in the housing 30. A locking block 139 protrudes from the second brim 133. The locking block 139 is locked to the housing 30.

A shaft 17 protrudes from the main portion 15, between the first masking portion 11 and the latch board 135. The shaft 17 is rotatably mounted to the housing 30. The shaft 17 includes a rotating portion 173 and a securing portion 171 connected to one end of the rotating portion 173. The securing portion 171 can be a bar block. The securing portion 171 defines a guiding surface 1711 away from the rotating portion 173. The guiding surface 1711 is used to guide the securing portion 171 to latch with the housing 30. The rotating portion 173 may be a round pole.

Referring to FIGS. 1 and 2, the housing 30 includes a bottom wall 31 and a peripheral wall 33 protruding from the bottom wall 31. The cover member 10 is secured to the peripheral wall 33. The peripheral wall 33 defines a first port 331 and a second port 333. The first port 331 may be for insertion of an earphone. The second port 333 may be for insertion of a plug (e.g., a power plug and an USB plug).

The peripheral wall 33's interior surface is recessed to define a cutout 3311, adjacent to the first port 331, thus forming a resisting wall 3313. The resisting block 1121 is received in the cutout 3311, and resists the resisting wall 3313. The bottom wall 31 defines a latching slot 3315, adjacent to the first port 331. The latching slot 3315 is used to receive and latch with part of the latching block 1131 (see FIG. 2). The peripheral wall 33 defines a receiving cavity 3317, adjacent to the first port 331. The receiving cavity 3317 receives the embedding block 115.

The peripheral wall 33 defines a through hole 3331, adjacent to the second port 333. The hole 3331 is configured for receiving the latch board 135. The peripheral wall 33 defines a receiving groove 3332 opposite to the hole 3331. The receiving groove 3332 is configured for receiving the protrusion 137. The bottom wall 31 defines a notch 3335. The notch 3335 is configured for receiving the locking block 139 (shown in FIG. 2).

The peripheral wall 33 defines a mounting hole 335 between the hole 3331 and the first port 331. The mounting hole 335 generally has the same size and shape as the securing portion 171. The mounting hole 335 extends vertical to the latch block 135. The securing portion 171 is biased to latch into the mounting hole 335, with the rotating portion 173 rotatably received in the mounting hole 335. Whereby the rotating portion 173 is rotated about 90 degree, the securing portion 171 resists the peripheral wall 33, thus tightly attaching the cover member 10 to the housing 30.

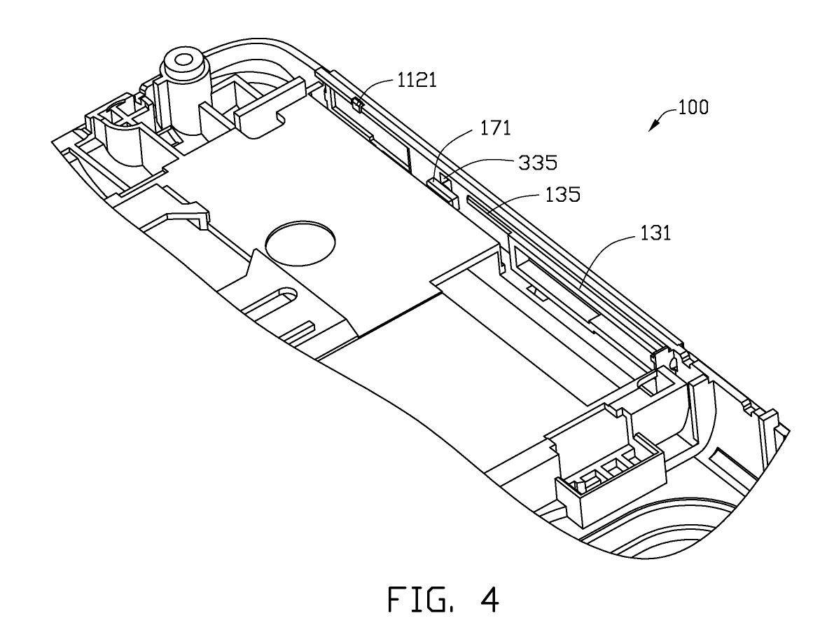

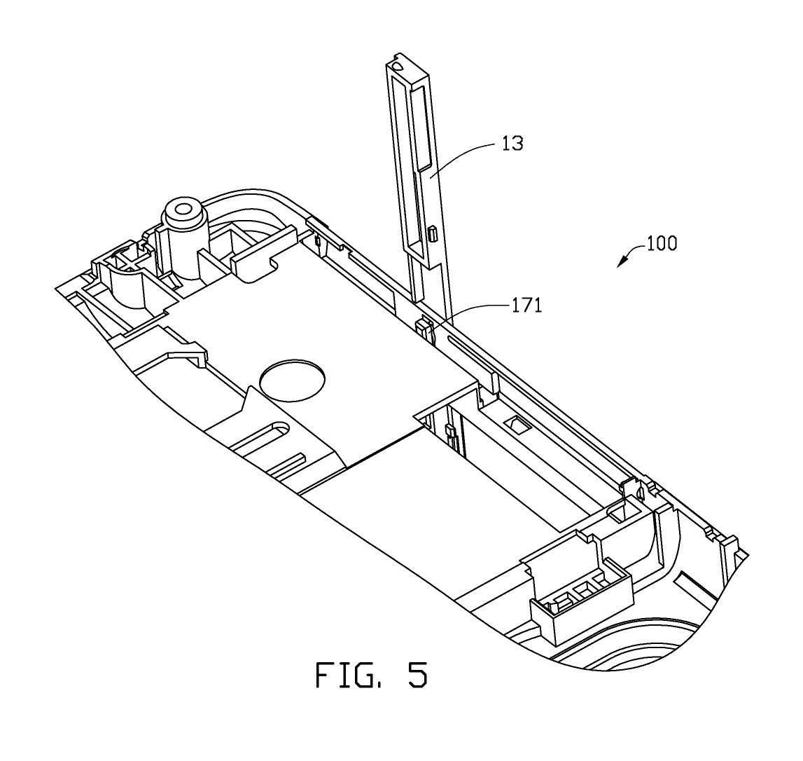

Referring to FIGS. 4 and 5, in assembly, the cover member 10 is placed adjacent to the peripheral wall 33, with the cover member 10 being substantially perpendicularly to the peripheral wall 33. The securing portion 171 is inserted through the mounting hole 335. The rotating portion 173 is then rotated about 90 degree. At this time, the securing portion 171 resists an inside of the peripheral wall 33, and the securing portion 171 is not easily removed from the mounting hole 335 when it is returned to the 90 Degree rotation, thus securing the cover member 10 to the housing 30.

To cover the first port 331 and the second port 332, the cover member 10 is rotated about the rotating portion 173 until the first masking portion 11 and the second masking portion 13 each cover the first port 331 and the second port 332. Then the cover member 10 is secured to the peripheral wall 33.

To expose the first port 331 and the second port 332, the cover member 10 is rotated about the rotating portion 173 to make the first port 331 and the second port 332 be exposed.

It is to be understood, however, that even through numerous characteristics and advantages of the present disclosure have been set forth in the foregoing description, together with details of the structure and function of the disclosure, the disclosure is illustrative only, and changes may be made in detail, especially in matters of shape, size, and arrangement of sections within the principles of the disclosure to the full extent indicated by the broad general meaning of the terms, in which the appended claims are expressed.

What is claimed is:

1. A portable electronic device comprising:
a cover member comprising a main portion, the main portion comprising a first masking portion and a second masking portion; a housing comprising a bottom wall and a peripheral wall protruding from the bottom wall, the peripheral wall defining a first port and a second port, the cover member being rotatably connected to the peripheral wall, the first masking portion being received in the first port, and the second masking portion being received in the second port; and
a shaft protruding from the main portion; wherein the shaft is located between the first masking portion and the second masking portion, and the cover member is rotatably mounted to the housing via the shaft.

2. The portable electronic device as claimed in claim 1, wherein the shaft comprises a rotating portion and a securing portion connected to one end of the rotating portion; the peripheral wall defines a mounting hole; and when the securing portion is inserted into the mounting hole, it resists an inside of the peripheral wall; and the rotating portion is rotatably received in the mounting hole.

3. The portable electronic device as claimed in claim 1, wherein the first masking portion is enclosed by two short sides, a first long side, and a second long side, the two short sides are opposite to each other, the two long sides are opposite to each other, a resisting block protrudes from the first long side, the peripheral wall's interior surface defines a cutout, and the resisting block is received in the cutout.

4. The portable electronic device as claimed in claim 3, wherein a latch block protrudes from the second long side, the bottom wall defines a latching slot, and the latching slot is used to receive and latch with part of the latching block.

5. The portable electronic device as claimed in claim 1, wherein the second masking portion is surrounded by a first brim and a second brim opposite to the first brim, a latch board protrudes from the first brim towards the first masking portion, the peripheral wall defines a through hole, and the hole is configured for receiving the latch board.

6. The portable electronic device as claimed in claim 1, wherein a protrusion protrudes from one end of the second masking portion in a direction away from the first masking portion, the peripheral wall defines a receiving groove opposite to the hole, and the receiving groove is configured for receiving the protrusion.

7. The portable electronic device as claimed in claim 5, wherein a locking block protrudes from the second brim, the bottom wall defines a notch, and the notch is configured for receiving the locking block.

8. A cover assembly, comprising:
a main portion comprising a first masking portion and a second masking portion; and
a shaft protruding from the main portion; wherein the shaft is located between the first masking portion and the second masking portion, and the main portion is rotatably mounted to a housing via the shaft.

9. The cover assembly as claimed in claim 8, wherein the shaft comprises a rotating portion and a securing portion connected to one end of the rotating portion.

10. The cover assembly as claimed in claim 8, wherein the extending direction of the securing portion is perpendicular to the extending direction of the main portion.
